(19) United States
(12) Patent Application Publication
(10) Pub. No.: US 2023/0296987 A1
(43) Pub. Date: Sep. 21, 2023

(54) TOOL DRIFT COMPENSATION WITH MACHINE LEARNING

(71) Applicant: Applied Materials, Inc., Santa Clara, CA (US)

(72) Inventors: YenShuo LIN, Tainan City (TW); Tamer COSKUN, San Jose, CA (US)

(21) Appl. No.: 18/019,054

(22) PCT Filed: Aug. 6, 2021
(86) PCT No.: PCT/US2021/045068

§ 371 Date: Jan. 31, 2023

Related U.S. Application Data
(60) Provisional application No. 63/064,838, filed on Aug. 12, 2020.

(51) Int. Cl. G03F 7/20; G06N 5/022

(52) U.S. Cl. CPC G03F 7/70508; G06N 5/022; G03F 7/2051; G03F 7/70516; G03F 7/70525

(57) ABSTRACT

Methods and systems for predictively determining tool drift in a digital lithography tool for early warning, and/or adjusting the tool in-situ to mitigate the effects of drift. Drift is measured during manufacturing by measuring alignment marks from eye-to-eye a bridge-to-bridge, among other methods. Measured drift is decomposed into three components: trend—trending drift over time, increment—rate of change of drift over time, and remaining—the difference between the drift, the trend, and the increment. Each component is provided to a machine learning engine, that predicts the next measurement of each component. Predicted measurements may be provided to the tool for use as adjustment parameters to modify how an eye module shoots a pattern onto a substrate, and/or as an early warning when predicted parameters are outside of a desired processing parameter window.

### BACKGROUND

### Field

Embodiments of the present disclosure generally relate to a digital lithography system, and more particularly to methods and systems to compensate for drift in a digital lithography system.

### Description of the Related Art

In semiconductor processing tools such as digital lithography systems, devices fabricated on a substrate, and circuitry connecting those devices may be impacted when the tool varies from the intended design. During normal operation of such a tool, a variety of factors may impact the precision and accuracy of the deposition of materials in forming desired structures. Fluctuations in temperature, humidity, pressure, and airflow, may change over time due to the operation of the tool, and/or the environment in which the tool is operating. These fluctuations may manifest as tool drift.

In prior approaches, to understand the impact of tool drift, substrate samples would be used to take metrology measurements, with adjustments to the tool provided to compensate for measured tool drift. Taking metrology measurements and then adjusting the tool is a cumbersome process, requiring many person-hours, in addition to identifying issues after the fact.

What is needed are methods and systems to overcome the issues presented by prior approaches, to predictively determine tool drift and perform tool adjustment in-situ.

### SUMMARY

The present disclosure generally to methods and systems for predictively determining tool drift in a digital lithography tool and adjusting the tool in-situ to mitigate the effects of drift. Drift is measured during manufacturing by measuring alignment marks from eye-to-eye a bridge-to-bridge, among other methods. Measured drift is decomposed into three components: trend—trending drift over time, increment—the rate of change of drift over time, and remaining—the difference between the drift, the trend, and the increment. Each component is provided to a machine learning engine that predicts the next measurement of each component. Predicted measurements are provided to the tool for use as adjustment parameters to modify how an eye module shoots a pattern onto a substrate.

In one embodiment, a method for drift compensation in a digital photolithography tool is disclosed, the method comprising receiving historical sensor data, receiving historical drift data correlated to the historical sensor data, and generating a trained machine learning model by training a machine learning model using the historical sensor data and the historical drift data. Embodiments further comprise processing a substrate using a digital photolithography tool comprising a sensor configured to produce sensor data, and an eye module, measuring drift of the digital photolithography tool, providing the sensor data and the measured drift to the trained machine learning model, receiving, from the trained machine learning model, predicted tool drift, and adjusting the eye module based on the predicted tool drift.

In another embodiment, a computer-readable medium containing computer-readable instructions for method for drift compensation in a digital lithography tool is disclosed, the method comprising receiving historical sensor data, receiving historical drift data correlated to the historical sensor data, and generating a trained machine learning model by training a machine learning model using the historical sensor data and the historical drift data. Embodiments further comprise processing a substrate using a digital photolithography tool comprising a sensor configured to produce sensor data, and an eye module, measuring drift of the digital photolithography tool, providing the sensor data and the measured drift to the trained machine learning model, receiving, from the trained machine learning model, predicted tool drift, and adjusting the eye module based on the predicted tool drift.

In another embodiment, a system for digital lithography is disclosed, the system comprising a processor configured to carry out a method for drift compensation in a digital lithography tool, the method comprising receiving historical sensor data, receiving historical drift data correlated to the historical sensor data, and generating a trained machine learning model by training a machine learning model using the historical sensor data and the historical drift data. Embodiments further comprise processing a substrate using a digital photolithography tool comprising a sensor configured to produce sensor data, and an eye module, measuring drift of the digital photolithography tool, providing the sensor data and the measured drift to the trained machine learning model, receiving, from the trained machine learning model, predicted tool drift, and adjusting the eye module in real time based on the predicted tool drift.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a digital lithography tool, according to disclosed embodiments.

FIG. 2 depicts a system for tool drift compensation in a digital lithography system, according to disclosed embodiments.

FIG. 3 is a machine learning model for predicting tool drift compensation in a digital lithography system, according to disclosed embodiments.

FIG. 4 depicts an example of drift data of a digital lithography system, according to disclosed embodiments.

FIG. 5 is a depicts example calculation methods for components of tool drift prediction, according to disclosed embodiments.

FIG. 6 depicts an example of drift data, trend data, increment data, and remaining data, according to disclosed embodiments.

FIG. 7 depicts a method for tool drift compensation, according to disclosed embodiments.

FIG. 8 depicts a computer system for tool drift compensation, according to disclosed embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The present disclosure generally relates to methods and systems for predictively determining tool drift in a digital lithography system, and adjusting the system in-situ to mitigate the effects of drift. In embodiments, tool drift is measured during manufacturing, for example, by measuring locations of alignment marks from eye-to-eye a bridge-to-bridge, among other methods. Measured drift is decomposed into three components: trend—measuring trending drift over time, increment—measuring the rate of change of drift over time, and remaining—measuring the difference between the drift, the, trend and the increment. Each component is provided to a machine learning engine and predicts the next measurement of each component. The predicted measurements are aggregated and provided to the tool for use as adjustment parameters, that will adjust how an eye module shoots a pattern onto a substrate.

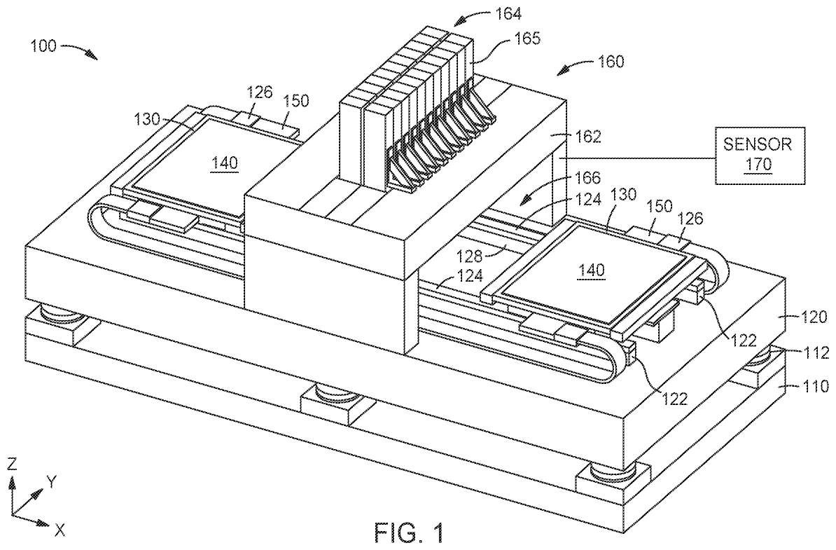

FIG. 1 depicts a perspective view of a system 100 that may benefit from embodiments disclosed herein. The system 100 includes a base frame 110, a slab 120, a stage 130, and a processing apparatus 160. The base frame 110 may rest on the floor of a fabrication facility and may support the slab 120. Passive air isolators 112 may be positioned between the base frame 110 and slab 120. The slab 120 may be a monolithic piece of granite, and stage 130 may be disposed on the slab 120. A substrate 140 may be supported by stage 130. A plurality of holes (not shown) may be formed in stage 130 for allowing a plurality of lift pins (not shown) to extend therethrough. The lift pins may rise to an extended position to receive the substrate 140, such as from a transfer robot (not shown). The transfer robot may position the substrate 140 on the lift pins, and the lift pins may, thereafter, gently lower the substrate 140 onto the stage 130.

The substrate 140 may, for example, be made of quartz and be used as part of a flat panel display. In other embodiments, the substrate 140 may be made of other materials. In some embodiments, the substrate 140 may have a photoresist layer formed thereon. A photoresist is sensitive to radiation and may be a positive photoresist or a negative photoresist, meaning that portions of the photoresist exposed to radiation will be respectively soluble or insoluble to photoresist developer applied to the photoresist after the pattern is written into the photoresist. The chemical composition of the photoresist determines whether the photoresist will be a positive photoresist or negative photoresist. For example, the photoresist may include at least one of diazonaphthoquinone, a phenol formaldehyde resin, poly(methyl methacrylate), poly(methyl glutarimide), and SU-8. In this manner, the pattern may be created on a surface of the substrate 140 to form the electronic circuitry.

The system 100 may further include a pair of supports 122 and a pair of tracks 124. The pair of supports 122 may be disposed on the slab 120, and the slab 120 and the pair of supports 122 may be a single piece of material. The pair of tracks 124 may be supported by the pair of the supports 122, and the stage 130 may move along the tracks 124 in the in-scan direction. In one embodiment, the pair of tracks 124 is a pair of parallel magnetic channels. As shown, each track 124 of the pair of tracks 124 is linear. In other embodiments, the track 124 may have a non-linear shape. An encoder 126 or another sensor may be coupled to the stage 130 in order to provide location information to a controller and may detect movement in a stage due to vibration. In some embodiments, encoder 126 may be an interferometer, or other device or sensor capable of detecting the location of a stage, the vibration of a stage, and in-scan and/or cross-scan deviation of a stage due to vibration.

The processing apparatus 160 may include a support 162, also known as a bridge, and a processing unit 164. The support 162 may be disposed on the slab 120 and may include an opening 166 for the stage 130 to pass under the processing unit 164. The processing unit 164 may be supported by the support 162. In one embodiment, the processing unit 164 is a pattern generator configured to expose a photoresist in a photolithography process. In some embodiments, the pattern generator may be configured to perform a maskless lithography process. The processing unit 164 may include a plurality of image projection systems disposed in a case. The combination of an image projection system and case is referred to herein as an “eye” or “eye module” 165. The processing apparatus 160 may be utilized to perform maskless direct patterning. Sensor 170 measures one or more conditions of the system 100, or environmental conditions in which system 100 operates. Conditions in this context may include and are not limited to temperature, pressure, humidity, airflow, vibration, or other conditions that may cause or affect drift in system 100. Although as described herein sensor 170 information may be provided to systems and methods disclosed herein to predict and adjust for tool drift, in some embodiments when sensor 170 senses conditions that may lead to drift, or actually cause drift, a warning may be provided to a user and/or equipment coupled to the system 100. Although sensor 170 is shown connected to support 162, sensor 170 may be positioned to measure conditions at any part of the system 100, or the environment in which system 100 is operating. Moreover, there may be more than one sensor 170.

During operation, one of the stage 130 moves in the in-scan direction from a loading position, as shown in FIG. 1, to a processing position. The processing position may refer to one or more positions of the stage 130 as the stage 130 passes under the processing unit 164. During operation, the stage 130 may be lifted by a plurality of air bearings and may move along the pair of tracks 124 from the loading position to the processing position. A plurality of vertical guide air bearings may be coupled to the stage 130 and positioned adjacent an inner wall 128 of each support 122 in order to stabilize the movement of the stage 130. The stage 130 may also move in the cross-scan direction by moving along a track 150 for processing and/or indexing the substrate 140.

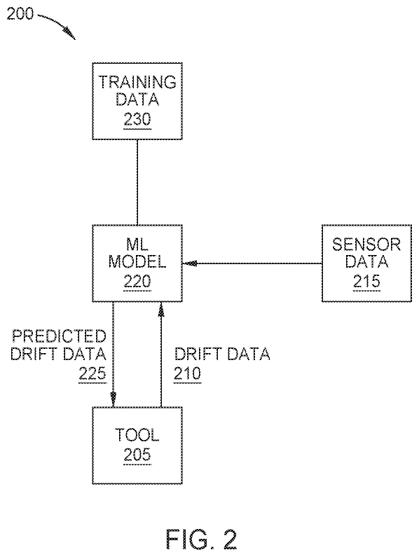

FIG. 2 depicts a system 200 for tool drift compensation in a digital lithography system, according to disclosed embodiments.

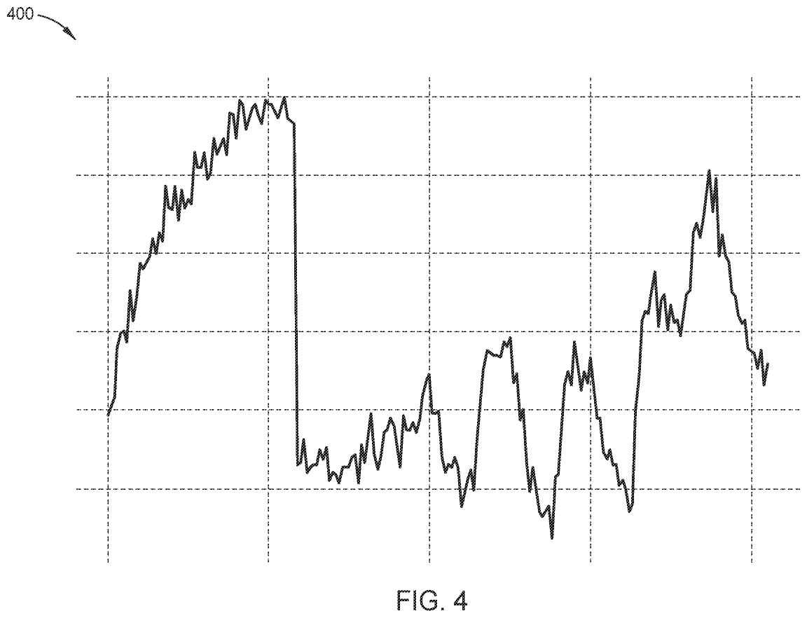

Tool 205, for example, may be the same as or similar to the digital lithography tool depicted above as system 100, of FIG. 1. During operation of the tool 205, a substrate, such as substrate 140, will pass under the bridge (e.g., support 162) to be processed by one or more eye modules (e.g., eye module 165) for patterning a photosensitive layer on the substrate. Also present on the substrate will be one or more alignment marks (not shown), patterned by one or more eye modules, and positioned to be measured by one or more eye modules. According to disclosed embodiments, upon measuring a difference in a cross-scan and/or in-scan direction as between two measurements of the same alignment mark, drift data 210 point may be recorded. An example of drift data may be seen in FIG. 4 that depicts an example of drift data 400 of a digital lithography system, according to disclosed embodiments. Differences in the measurements of the same alignment mark as between different eye modules (either on the same or different bridges) may be caused by the movement of an eye module, a bridge, a stage, the tracks upon which the stage travels, or other components of the digital lithography system. Temperature, humidity, pressure, airflow, vibration, and other factors may cause movement of one or more of these components. According to disclosed embodiments, when an alignment mark is measured, sensor data 215, such as from sensor 170, is measured as well to be used in the analysis discussed below.

Drift data 210 and sensor data 215 may be provided in real time to a machine learning model (ML model) 220 for further processing and will be discussed in greater detail below. As would be appreciated by one of skill in the art, in some embodiments, sensor data 215 may be used as a label for drift data 210. According to disclosed embodiments, ML model 220 may be a linear regression model, but any supervised learning model may be used, and in some embodiments, an unsupervised learning model is utilized.

Upon processing the drift data 210, ML model 220 may produce predicted drift data 225 in real time that will be provided to the tool 205 to modify the operation of one or more eye modules to compensate in real time for predicted drift. It should be understood that according to disclosed embodiments, compensation for drift predicted by ML model 220 will be applied to modify the output of the eye module in real time (or in some embodiments at a time appropriate for mitigation of tool drift), and there is no need to physically move any component of the tool 205. In alternate embodiments, one of skill in the art may physically move one or more components of the tool either automatically or manually, in applying predicted drift data 225 to mitigate drift.

In some embodiments, an operational window is defined for one or more elements of predicted drift data 225, to enable an early warning for predicted drift. In embodiments, there may be three states of early warning, based upon the predicted drift data 225 in relation to the operational window.

Predicted drift data 225 well within the operational window will trigger no warning and allow the tool 205 to continue operation. Predicted drift data that is close, for example within a standar deviation (or other data-based operational threshold), of the operational window will trigger a warning to a user, who may choose to alter operation of the tool 205, including stopping operation of the tool 205. If predicted drift data 225 is developed that is outside of the operational window, an error alert will be provided to a user and will automatically alter operation of the tool 205, including stopping operation of the tool 205.

In embodiments that include the early warning, in some embodiments an early warning machine learning (ML) model (not shown) may be included. The early warning ML model in embodiments may be trained using historical drift data, predicted drift data, and simulated drift data as described herein, from a particular tool, or set of tools, so as to train the appropriate operational window parameters for the tool 205 that trigger the above-described warnings. Once trained with historic, simulated, or synthetic predicted data, the early warning ML model may receive real time, or ‘live’, predicted drift data 225 as a result of manufacturing operation of the tool 205 so as to provide the above-described warnings (e.g., good—no warning provided, continued tool operation; warning provided to user, who may choose to alter operation of the tool; error alert provided to user and automatic alteration of operation of the tool, such as stopping operation of the tool) during manufacturing operations.

In some embodiments, prior to providing predicted drift data 225 to the tool 205, ML model 220 receives training data 230 so as to train the ML model. Training data 230 may be synthetic or simulated data developed specifically for training the ML model 220, or historical data derived from previous runs of the tool 205 and/or similar tools having similar drift characteristics, or from previous measurements of alignment marks during real time processing. In some embodiments, training data 230 may further comprise sensor data 215 and predicted data 225 from the current operations of the tool 205, in a form of ‘online’ or real-time updating and/or training of the ML model 220.

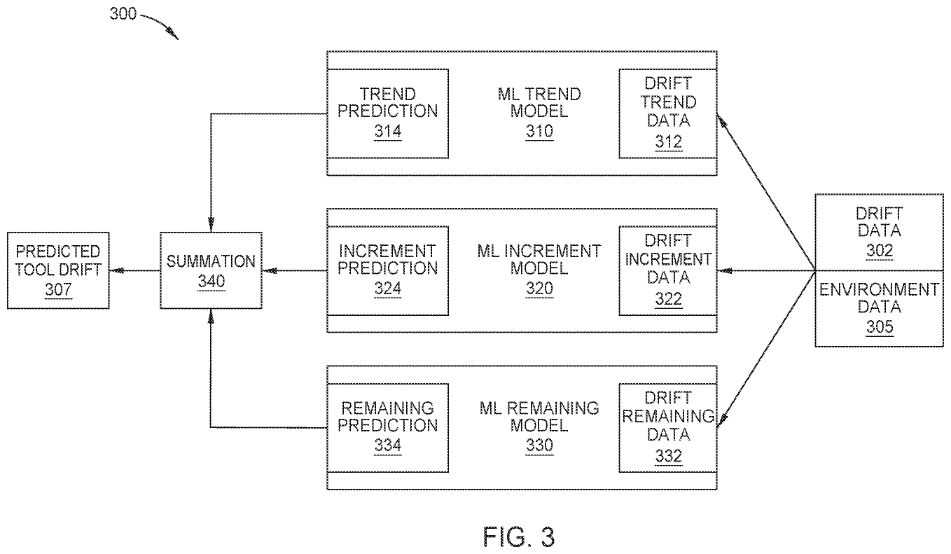

FIG. 3 depicts an ML model 300 for predicting tool drift, according to disclosed embodiments. ML model 300 receives drift data 302 from the tool, such as system 100 of FIG. 1, from data acquired by sensor 170. In some embodiments, one or more elements of drift data 302 are real time measurements from sensor 170. In embodiments, some drift data 302 may be historic data from previous runs of the tool, or calculated data, based on previous runs, experimentation or other factors. In embodiments that use historic or calculated data, these may be used in addition to, or in place of real time drift data 302, for example, if real time data is not available for one or more measurement cycles, or if alternate points drift data 302 is desired. Moreover, one or more ML models of ML model 300 are trained using historic data from previous operation of one or more tools. ML model 300 decomposes drift data 302 into three components, discussed below, then proceeds to calculate predicted values for these three values. ML model 300 is comprised of three machine learning models, each of which generates the predicted values. The results of the predicted values are summed to produce a predicted tool drift 307. One or more of the described ML models may comprise a linear regression model or other supervised or unsupervised machine learning model. In some embodiments ML models such as linear regression, xgboost, random forest, support vector regression, neural networks, recurrent neural networks, long short-term memory (LSTM), Elastic Net, Lasso, Ridge, Bayesian regression, decision tree, and/or nearest neighbor regression may be used, either alone or in combination with others.

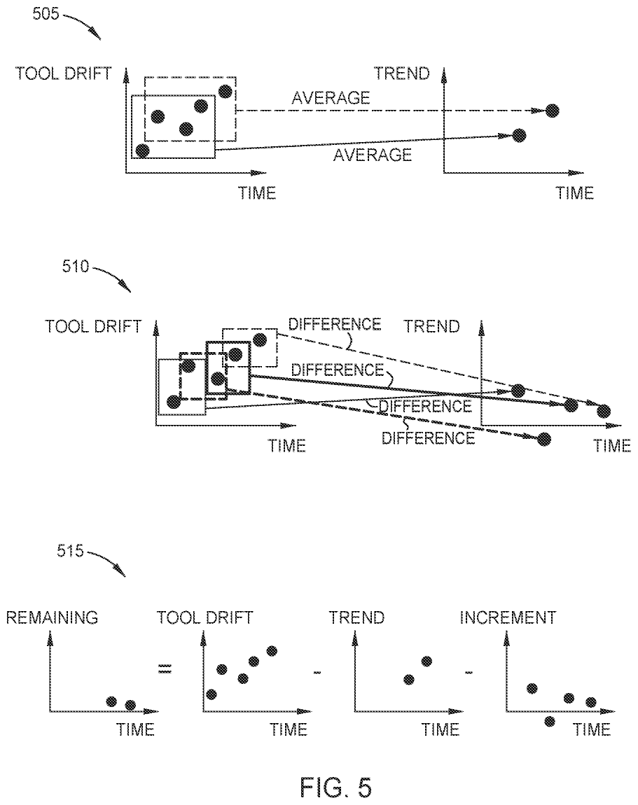

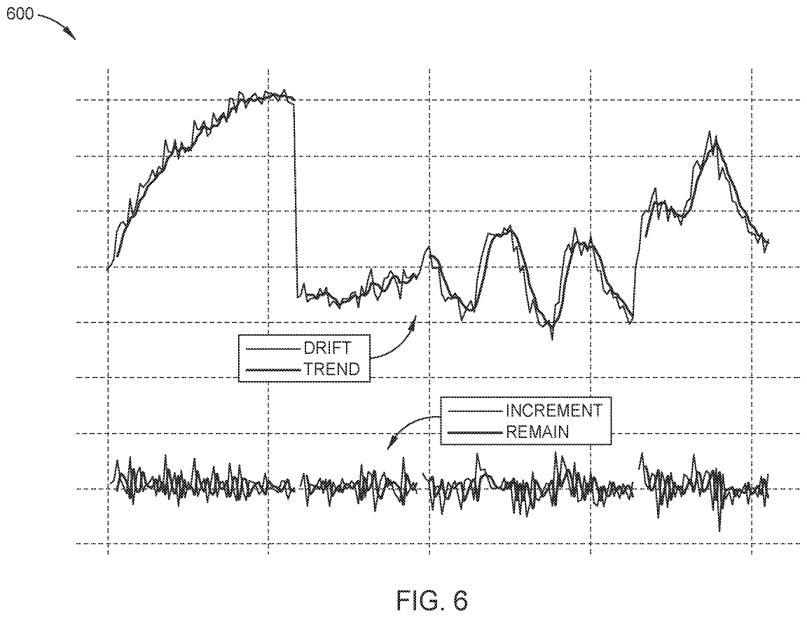

ML trend model 310 receives drift data 302, such as drift data 210 of FIG. 2, and calculates drift trend data 312 from it. An example plot of drift data over time can be seen in FIG. 4. In some embodiments, drift data 302 may be real-time data from a tool in operation, while in other embodiments, such as those for training ML trend model 310, drift data may be historical data from the same or similar tools, or synthetic data. Drift trend data 312, in embodiments, may be an average of drift data 302 points over discrete time periods, representing an average drift data value for a given time period, such as depicted in FIG. 5, element 505. An example of the relationship of drift data 302 to drift trend data 312 may be seen in FIG. 6 that depicts an example 600 of drift data, trend data, increment data, and remaining data, according to disclosed embodiments. Although an average of drift data 302 points is depicted, there are many types of averages that may be used in this context, such as a weighted average, exponential average, or other type of average capable of depicting a trend of the drift data 315. ML trend model 310 uses linear regression, or other ML model or algorithm, with the drift trend data 312 to predict one or more of the next points in the drift trend, resulting in trend prediction 314. In embodiments, environment data 305, for example, sensor data from sensor 170 of FIG. 1, may be utilized by the ML trend model 310 to label drift data 302, drift trend data 312, and/or trend prediction 314.

ML increment model 320 receives drift data 302 and calculates drift increment data 322 from it. Drift increment data 322, in embodiments, may be a difference between two points of drift data 302 in a given time period, and represents the rate of change, or velocity, of drift, over time. An example of a calculation of drift increment data 322 may be seen in FIG. 5, element 510, and a relationship between drift data 302 and drift increment data 322 may be seen in FIG. 6. ML model 320 uses linear regression, or other ML models or algorithms, with the drift increment data 322 to predict one or more of the next points in the drift increment data 322, resulting in increment prediction 324. In embodiments, environment data 305, may be utilized by the ML increment model 320 to label drift data 302, drift increment data 322, and/or increment prediction 324.

ML remaining model 330 receives drift data 302 and calculates drift remaining data 332 from it. Drift remaining data 332, in embodiments, may be a difference between drift data 302, drift trend data 312, and drift increment data 322, and represents additional factors impacting tool drift over time that is not otherwise accounted for. An example of a calculation of drift remaining data 332 may be seen in FIG. 5, element 515, and a relationship between drift data 302 and drift remaining data 332 may be seen in FIG. 6. ML remaining model 330 uses linear regression, or other ML models or algorithms, with drift remaining data 332 to predict one or more of the next points in the drift remaining data 332, resulting in remaining prediction 334. In embodiments, environment data 305 may be utilized by the ML remaining model 330 to label drift data 302, drift remaining data 332, and/or remaining prediction 334.

Upon generation of trend prediction 314, increment prediction 324, and remaining prediction 334, ML model 300 aggregates these values via summation 340, providing the result as predicted tool drift 307. Predicted tool drift 307 is provided to a digital lithography tool, such as an eye module 165 of system 100 of FIG. 1, that applies the predicted tool drift 307 to adjust the shot location and/or pattern generated by an eye module for projection to a substrate. Predicted tool drift 307 that is provided to the eye module adjust operation of the eye module by updating software parameters, as opposed to movement of a physical component of the eye. In embodiments, if the predicted tool drift 307, or component thereof such as trend prediction 314, increment prediction 324, and/or remaining prediction 334 exceeds a predetermined threshold, a warning may be provided to a user and/or equipment coupled to the system (such as system 100 of FIG. 1), in addition to, or instead of, adjusting the tool to mitigate the effects of tool drift.

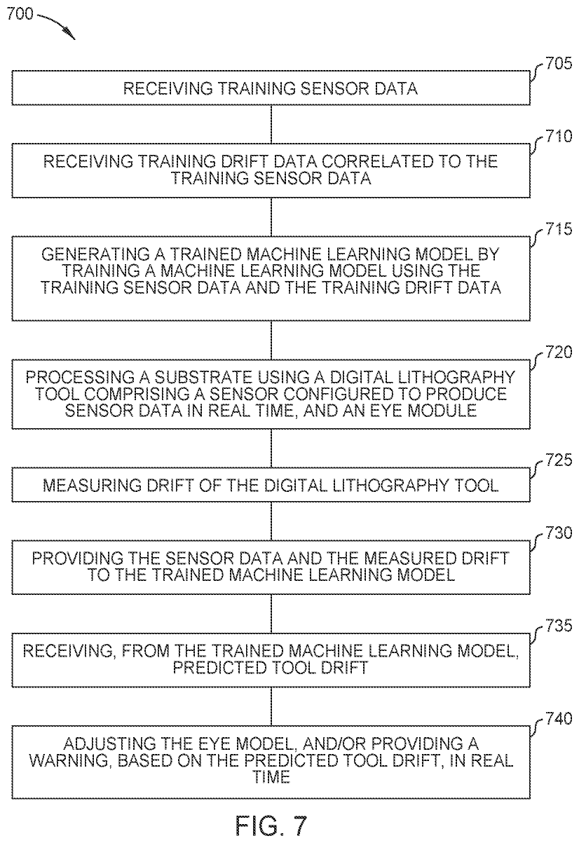

FIG. 7 depicts a method 700 for tool drift compensation according to disclosed embodiments.

At block 705, the method 700 receives historical sensor data, and at block 710 receives historical drift data correlated to the historical sensor data.

At block 715, the method generates a trained machine learning model by training a machine learning model using the historical sensor data and the historical drift data. In embodiments the machine learning model comprises an ML trend model receiving measured drift and configured to generate a trend prediction of future drift, an ML increment model receiving rate of change of measured drift and configured generate an increment prediction of future drift, and an ML remaining model receiving a difference between the measured drift, the predicted trend and the predicted increment, and configured to generate a predicted remaining value comprising a predicted difference between future drift and predicted rate of change of future drift. In some embodiments, one of the ML trend model, the ML increment model, and the ML remaining model comprises a linear regression model.

At block 720, the method 700 processes a substrate using a digital lithography tool, the tool comprising a sensor configured to produce real time sensor data and an eye module. At block 725, the drift of the digital lithography tool is measured, and providing the sensor data and measure drift to the trained machine learning model at block 730. In embodiments, sensor data comprises one of temperature, humidity, and pressure. In embodiments, measuring the drift comprises measuring the location of a first alignment mark and a second alignment mark on the substrate, and measuring the location of the first alignment mark and second alignment mark is performed using one of the eye module and a second eye module. In some embodiments, measuring the drift may comprise metrology measurements of the substrate.

At block 735, the method receives from the trained machine learning model, predicted tool drift, and adjusts the eye module in real time based on the predicted tool drift at block 740. In this context, adjusting the eye module comprises adjusting software parameters within the eye module to modify a location of a shot image on a substrate, as opposed to physically moving a component of the tool, or the substrate. In some embodiments, a warning based on the predicted tool drift is provided based on the predicted tool drift, the warning comprising updating a user display and altering the operation of the tool.

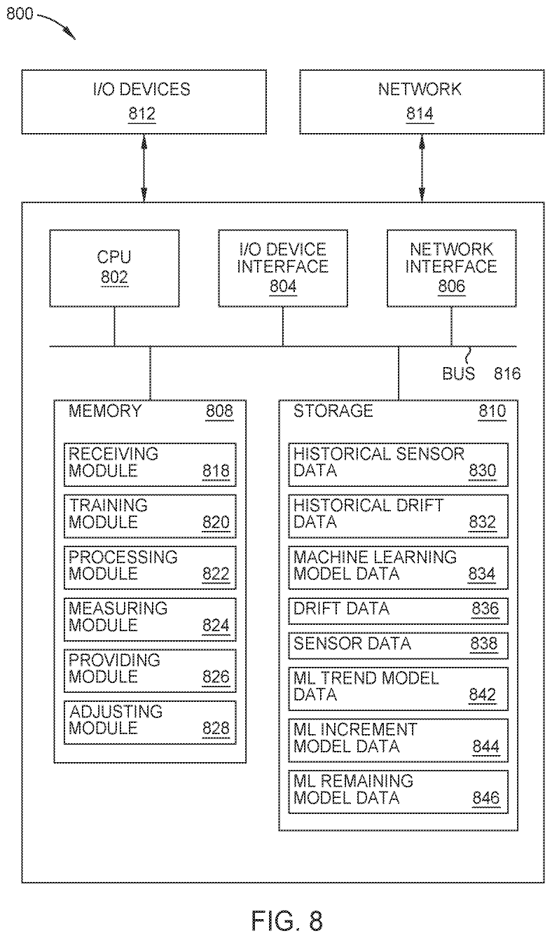

FIG. 8 depicts a system 800 for tool drift compensation, according to disclosed embodiments, that may perform methods described herein, such as the method for tool drift compensation as described with respect to FIGS. 1-7, and in embodiments may be a part of, or coupled to, the digital lithography system depicted in FIG. 1.

System 800 includes a central processing unit (CPU) 802 connected to a data bus 816. CPU 802 is configured to process computer-executable instructions, e.g., stored in memory 808 or storage 810, and to cause the system 800 to perform methods described herein, for example, with respect to FIGS. 1-7. CPU 802 is included to be representative of a single CPU, multiple CPUs, a single CPU having multiple processing cores, and other forms of processing architecture capable of executing computer-executable instructions. In some embodiments, CPU 802 may be an FPGA or a GPU, and in some embodiments, multiple CPUs, FPGA's, and/or GPU's may be used.

System 800 further includes input/output (I/O) device(s) 812 and interfaces 804, which allows system 800 to interface with input/output devices 812, such as, for example, keyboards, displays, mouse devices, pen input, and other devices that allow for interaction with system 800. Note that system 800 may connect with external I/O devices through physical and wireless connections (e.g., an external display device).

System 800 further includes a network interface 806, which provides system 800 with access to external network 814 and thereby external computing devices.

System 800 further includes memory 808, which in this example includes a receiving module 818, a training module 820, a processing module 822, a measuring module 824, a providing module 826, and an adjusting module 828, for performing operations described in FIGS. 1-5.

Note that while shown as a single memory 808 in FIG. 8 for simplicity, the various aspects stored in memory 808 may be stored in different physical memories, including memories remote from system 800, but all accessible by CPU 802 via internal data connections such as bus 816.

Storage 810 includes historical sensor data 830 and historical drift data 832, which may be like historical data described in connection with FIGS. 1-7.

Storage 810 further includes machine learning model data 834, which may be like machine learning models described in connection with FIGS. 1-7.

Storage 810 further includes drift data 836 and sensor data 838, which may be like drift and sensor data described in connection with FIGS. 1-7.

Storage 810 further includes ML trend model data 842, ML increment model data 844, and ML remaining model data 846, which may be like ML trend models, ML increment models, and ML remaining model data, described in connection with FIGS. 1-7.

To facilitate understanding, identical reference numerals have been used, where possible, to designate identical elements that are common to the figures. It is contemplated that elements disclosed in one embodiment may be beneficially utilized on other embodiments without specific recitation.

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a c c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

A processing system may be implemented with a bus architecture. The bus may include any number of interconnecting buses and bridges depending on the specific application of the processing system and the overall design constraints. The bus may link together various circuits including a processor, machine-readable media, and input/output devices, among others. A user interface (e.g., keypad, display, mouse, joystick, etc.) may also be connected to the bus. The bus may also link various other circuits such as timing sources, peripherals, voltage regulators, power management circuits, and other circuit elements that are well known in the art, and therefore, will not be described any further. The processor may be implemented with one or more general-purpose and/or special-purpose processors. Examples include microprocessors, microcontrollers, DSP processors, and other circuitry that can execute software. Those skilled in the art will recognize how best to implement the described functionality for the processing system depending on the particular application and the overall design constraints imposed on the overall system.

If implemented in software, the functions may be stored or transmitted over as one or more instructions or code on a computer-readable medium. Software shall be construed broadly to mean instructions, data, or any combination thereof, whether referred to as software, firmware, middleware, microcode, hardware description language, or otherwise. Computer-readable media include both computer storage media and communication media, such as any medium that facilitates the transfer of a computer program from one place to another. The processor may be responsible for managing the bus and general processing, including the execution of software modules stored on the computer-readable storage media. A computer-readable storage medium may be coupled to a processor such that the processor can read information from, and write information to, the storage medium. In the alternative, the storage medium may be integral to the processor. By way of example, the computer-readable media may include a transmission line, a carrier wave modulated by data, and/or a computer readable storage medium with instructions stored thereon separate from the wireless node, all of which may be accessed by the processor through the bus interface. Alternatively, or in addition, the computer-readable media, or any portion thereof, may be integrated into the processor, such as the case may be with cache and/or general register files. Examples of machine-readable storage media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product.

A software module may comprise a single instruction, or many instructions, and may be distributed over several different code segments, among different programs, and across multiple storage media. The computer-readable media may comprise a number of software modules. The software modules include instructions that, when executed by an apparatus such as a processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During the execution of the software module, the processor may load some of the instructions into cache to increase access speed. One or more cache lines may then be loaded into a general register file for execution by the processor. When referring to the functionality of a software module, it will be understood that such functionality is implemented by the processor when executing instructions from that software module.

The following claims are not intended to be limited to the embodiments shown herein but are to be accorded the full scope consistent with the language of the claims. Within a claim, a reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. A method for drift compensation in a digital photolithography tool, comprising:
receiving training sensor data;
receiving training drift data correlated to the training sensor data;
generating a trained machine learning model by training a machine learning model using the training sensor data and the training drift data;
processing a substrate using a digital lithography tool comprising a sensor configured to produce sensor data, and an eye module;
measuring drift of the digital lithography tool;
providing the sensor data and the measured drift to the trained machine learning model;
receiving, from the trained machine learning model, predicted tool drift; and
adjusting the eye module based on the predicted tool drift.

2. The method of claim 1, wherein the sensor data comprises one of a temperature, humidity, and pressure.

3. The method of claim 1, wherein measuring the drift comprises measuring locations of a first alignment mark and a second alignment mark on the substrate.

4. The method of claim 3, wherein measuring the locations of the first alignment mark and the second alignment mark is performed using one of the eye module and a second eye module.

5. The method of claim 1, further comprising providing a warning based on the predicted tool drift, the warning comprising updating a user display and altering operation of the digital lithography tool.

6. The method of claim 1, wherein the machine learning model comprises:
an ML trend model receiving measured drift and configured to generate a trend prediction of future drift;
an ML increment model receiving rate of change of measured drift and configured generate an increment prediction of future drift; and
an ML remaining model receiving a difference between the measured drift and the trend prediction of future drift and the increment prediction of future drift, and configured to generate a predicted remaining value comprising a predicted difference between future drift, the trend prediction of future drift, and the increment prediction of future drift.

7. The method of claim 6, wherein one of the ML trend model, the ML increment model, and the ML remaining model comprises a linear regression model.

8. A method for drift compensation in a digital lithography tool comprising:
processing a substrate using a digital photolithography tool comprising a sensor configured to produce sensor data, and an eye module;
measuring drift of the digital photolithography tool;
providing the sensor data and the measured drift to a trained machine learning model trained using training sensor data and training drift data correlated to the training sensor data;
receiving, from the trained machine learning model, predicted tool drift; and
adjusting the eye module based on the predicted tool drift.

9. The method of claim 8, wherein the sensor data comprises one of temperature, humidity, and pressure.

10. The method of claim 8, wherein measuring the drift comprises measuring locations of a first alignment mark and a second alignment mark on the substrate.

11. The method of claim 10, wherein measuring the locations of the first alignment mark and the second alignment mark is performed using one of the eye module and a second eye module.

12. The method of claim 8, further comprising providing a warning based on the predicted tool drift, the warning comprising updating a user display and altering operation of the digital lithography tool.

13. The method of claim 8, wherein the trained machine learning model is generated by training a machine learning model, the machine learning model comprises:
an ML trend model receiving measured drift and configured to generate a trend prediction of future drift;
an ML increment model receiving rate of change of measured drift and configured generate an increment prediction of future drift; and
an ML remaining model receiving a difference between the measured drift and the trend prediction of future drift and the increment prediction of future drift, and configured to generate a predicted remaining value comprising a predicted difference between future drift, the trend prediction of future drift, and the increment prediction of future drift.

14. The method of claim 13, wherein one of the ML trend model, the ML increment model, and the ML remaining model comprises a linear regression model.

15. A system for digital lithography, comprising:
a processor configured to carry out a method for drift compensation in a digital lithography tool, the method comprising:
receiving training sensor data;
receiving training drift data correlated to the training sensor data;
generating a trained machine learning model by training a machine learning model using the training sensor data and the training drift data;
processing a substrate using a digital photolithography tool comprising a sensor configured to produce sensor data, and an eye module;
measuring drift of the digital photolithography tool;
providing the sensor data and the measured drift to the trained machine learning model;
receiving, from the trained machine learning model, predicted tool drift; and
adjusting the eye module based on the predicted tool drift in real time.

16. The system of claim 15, wherein the sensor data comprises one of temperature, humidity, and pressure.

17. The system of claim 15, wherein measuring the drift comprises measuring locations of a first alignment mark and a second alignment mark on the substrate.

18. The system of claim 17, wherein measuring the locations of the first alignment mark and the second alignment mark is performed using one of the eye module and a second eye module.

19. The system of claim 15, further comprising providing a warning based on the predicted tool drift, the warning comprising updating a user display and altering operation of the digital lithography tool.

20. The system of claim 15, wherein the machine learning model comprises:
an ML trend model receiving measured drift and configured to generate a trend prediction of future drift;
an ML increment model receiving rate of change of measured drift and configured generate an increment prediction of future drift; and
an ML remaining model receiving a difference between the measured drift and the trend prediction of future drift and the increment prediction of future drift, and configured to generate a predicted remaining value comprising a predicted difference between future drift, the trend prediction of future drift, and the increment prediction of future drift.
